(19) United States
(12) Patent Application Publication
(10) Pub. No.: US 2007/0069196 A1
(43) Pub. Date: Mar. 29, 2007

(54) Epitaxial wafer for LED and light emitting diode

(75) Inventors: Manabu Kako, Hitachi (JP); Takehiko Tani, Hitachi (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: HITACHI CABLE, LTD., Tokyo (JP)

(21) Appl. No.: 11/377,431

(22) Filed: Mar. 17, 2006

(30) Foreign Application Priority Data
Sep. 26, 2005 (JP) 2005-277716

(51) Int. Cl. H01L 29/06

(52) U.S. Cl. 257/25

(57) ABSTRACT

An epitaxial wafer for a light emitting diode has: a light-emitting portion having a n-type cladding layer, a p-type cladding layer and an active layer formed between the n-type cladding layer and the p-type cladding layer, the light-emitting portion being formed on a n-type substrate; and a p-type GaP current spreading layer formed on the light-emitting portion. The p-type GaP current spreading layer is doped with Mg and has a root mean square roughness Rms of 15 nm to 5 μm on its surface.

The present application is based on Japanese patent application No. 2005-277716, the entire contents of which are incorporated herein by reference.

### BACKGROUND OF THE INVENTION

1. Field of the Invention

This invention relates to an epitaxial wafer for a high-brightness LED and a light emitting diode (LED) fabricated by using the epitaxial wafer.

2. Description of the Related Art

Light emitting diodes (LED's) are in wide use as a display device for industrial or consumer use. AlGaAs red LED's are used as a high-brightness LED. LED's with a shorter wavelength than red are of GaAsP or GaP, and they are not sufficient in brightness.

In recent years, AlGaInP-based crystal layer has been grown by MOVPE (metal-organic vapor phase epitaxy). Therefore, a high-brightness LED to emit orange, yellow or green light can be fabricated (e.g., JP-A-2001-102627).

The LED disclosed in JP-A-2001-102627 comprises, sequentially grown on an n-type GaAs substrate by MOVPE, an n-type GaAs buffer layer, an n-type AlGaInP cladding layer, an AlGaInP active layer, a p-type AlGaInP cladding layer, and a Zn-doped p-type GaP current spreading layer. The LED can effectively extract emitted light as compared to one without the p-type GaP current spreading layer.

It is known that a surface (epi-surface) of an epitaxial layer is roughened to enhance light extraction efficiency. The epi-surface is roughened generally by being etched after growing the epitaxial layer (e.g., JP-A-2002-217451).

JP-A-2002-217451 discloses a method that its light extraction surface is formed uneven by wet etching the surface of the epitaxial layer by using a mixture liquid of nitric acid and methanol.

In the conventional LED, when the Zn-doped GaP current spreading layer is epitaxially grown as thick as 5 μm or more, a lot of triangle or rhombic surface defects are generated. The chip may crack along the defect in the chip process. Because of this, the yield lowers.

Further, in the conventional method of roughening the light extraction surface, an additional process is needed to prevent the cracking after the epitaxial growth. Because of this, the fabrication cost must be increased.

### SUMMARY OF THE INVENTION

It is an object of the invention to provide an epitaxial wafer for LED that can have higher light extraction efficiency as well as a higher yield without requiring the additional process after the epitaxial growth.

It is a further object of the invention to provide a light emitting diode (LED) fabricated by using the epitaxial wafer.

(1) According to one aspect of the invention, an epitaxial wafer for a light emitting diode comprises:

a light-emitting portion comprising a n-type cladding layer, a p-type cladding layer and an active layer formed between the n-type cladding layer and the p-type cladding layer, the light-emitting portion being formed on a n-type substrate; and

a p-type GaP current spreading layer formed on the light-emitting portion,

wherein the p-type GaP current spreading layer is doped with Mg and comprises a root mean square roughness Rms of 15 nm or more and 5 μm or less on its surface.

In the epitaxial wafer for a light emitting diode of the invention, since the surface roughness of the p-type GaP current spreading layer is 15 nm or more in Rms, light reflected on the interface between the surface of the p-type GaP current spreading layer and the air can be reduced to enhance the light extraction efficiency. On the other hand, when the surface roughness of the p-type GaP current spreading layer is more than 5 μm in Rms, it is hard to conduct an image recognition in mechanical wire bonding.

Since the p-type GaP current spreading layer can be formed thick, the current can be more spread laterally and light can be emitted from a wider region of the light-emitting portion to enhance the light extraction efficiency.

Even when the Mg-doped p-type GaP current spreading layer is epitaxially grown thick, the triangle or rhombic surface defect is less likely to occur. Therefore, the chip is less likely to crack along the defect in the chip process, and the yield of the chip process can be thus enhanced.

(2) According to another aspect of the invention, a light emitting diode comprises:

an epitaxial wafer that comprises a light-emitting portion comprising a n-type cladding layer, a p-type cladding layer and an active layer formed between the n-type cladding layer and the p-type cladding layer, the light-emitting portion being formed on a surface of a n-type substrate, and a p-type GaP current spreading layer formed on the light-emitting portion, wherein the p-type GaP current spreading layer is doped with Mg and comprises a root mean square roughness Rms of 15 nm to 5 μm on its surface;

a back surface electrode formed on a surface of the n-type substrate that is opposite to the surface on which the light-emitting portion is formed; and

a surface electrode formed on the p-type GaP current spreading layer.

In the above invention (1) or (2), the following modifications and changes can be made.

(i) The p-type GaP current spreading layer is doped with C in addition to the Mg to allow a root mean square roughness Rms of 15 nm or more and 5 μm or less on its surface.

(ii) The p-type GaP current spreading layer is grown by MOVPE by using a biscyclopentadienyl magnesium as a source of the Mg.

(iii) The p-type GaP current spreading layer is autodoped with C that is contained in an organic metal material comprising Ga.

(iv) The p-type GaP current spreading layer comprises the Mg at an atomic concentration of 1×10¹⁷ cm⁻³ or more.

(v) The p-type GaP current spreading layer comprises the Mg and the C respectively at an atomic concentration of 1×10¹⁷ cm⁻³ or more.

(vi) The n-type substrate comprises GaAs, and

the light-emitting portion comprises AlGaInP or GaInP.

<Advantages of the Invention>

Since the p-type GaP current spreading layer is roughened by Mg doped thereinto, the additional post-process for the surface roughening is not needed after the epitaxial growth. Therefore, the epitaxial wafer for LED and the LED can have higher light extraction efficiency as well as a higher yield.

### BRIEF DESCRIPTION OF THE DRAWINGS

The preferred embodiments according to the invention will be explained below referring to the drawings, wherein:

FIG. 1 is a cross sectional view showing a light emitting diode in a preferred embodiment according to the invention;

FIG. 2A is a photograph (AFM image) showing a surface roughness Rms=7 nm of a Zn-doped GaP layer(with a thickness of 10 μm);

FIG. 2B is a photograph (AFM image) showing a surface roughness Rms=20 nm of a Mg-doped GaP layer (with a thickness of 10 μm);

FIG. 2C is a photograph (SEM image) showing a surface roughness Rms=7 nm of the Zn-doped GaP layer (with a thickness of 10 μm); and

FIG. 2D is a photograph (SEM image) showing a surface roughness Rms=20 nm of the Mg-doped GaP layer (with a thickness of 10 μm).

### DETAILED DESCRIPTION OF THE PREFERRED EMBODIMENTS

### First Embodiment

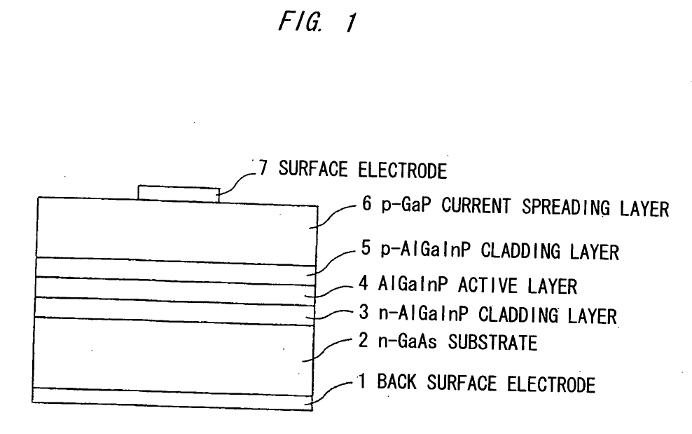

FIG. 1 is a cross sectional view showing a light emitting diode in the first preferred embodiment according to the invention.

The epitaxial wafer for LED comprises, sequentially grown on a n-type GaAs substrate 2 by MOVPE, a n-type AlGaInP cladding layer 3, an undoped AlGaInP active layer 4, and a p-type AlGaInP cladding layer 5. On the p-type AlGaInP cladding layer 5, a Mg-doped p-type GaP current spreading layer 6 is grown by MOVPE.

In fabricating a LED by using the epitaxial wafer for LED, a back surface electrode 1 is formed on the back surface of the n-type GaAs substrate 2, and a surface electrode 7 is formed, e.g., circular, at the center of the p-type GaP current spreading layer 6. The back surface electrode 1 can be, e.g., a stacked electrode of AuGe/Ni/Au. The surface electrode 7 can be, e.g., a stacked electrode of AuZn/Ni/Au or Ti/Pt/Au.

The Mg-doped p-type GaP current spreading layer 6 is epitaxially grown at a V/III ratio of 1 to 100 by using trimethylgallium (=Ga (CH₃)₃) and/or triethylgallium (=Ga (C₂H₅)₃), while doping Mg at an atom concentration of 1×10¹⁷ cm⁻³ or more. Thus, the p-type GaP current spreading layer 6 has a root mean square roughness Rms of 15 nm or more.

(Light-Emitting Operation)

The light-emitting operation of the LED will be explained below.

When a predetermined drive voltage is applied between the back surface electrode 1 and the surface electrode 7, a current flows from the surface electrode 7 toward the back surface electrode 1. Due to the p-type GaP current spreading layer 6, the current spreads laterally to allow the light emission in the wide region of the active layer 4. A part of light emitted from the active layer 4 is externally radiated through an exposed portion of the p-type GaP current spreading layer 6, i.e., a portion where the surface electrode 7 is not formed. In this case, when the surface of the p-type GaP current spreading layer 6 is flat, only light with a limited incident angle can be externally radiated at the interface of the p-type GaP current spreading layer 6 and the air since there is a difference in refractive index between the p-type GaP current spreading layer 6 (with a refractive index of about 3) and the air (with a refractive index of 1). The other light reflects on the interface and will be absorbed by the epitaxial layer. Therefore, the light extraction efficiency lowers. In contrast, in the embodiment of the invention, since the p-type GaP current spreading layer 6 is provided with the uneven surface, the incident angle operable to externally radiate the emitted light through the interface increases and, therefore, the amount of light to be reflected on the interface can be reduced. As a result, the light extraction efficiency increases.

(Effects of the First Embodiment)

The following effects can be obtained by the first embodiment of the invention.

(i) The epitaxial wafer for LED and the light emitting diode can have a higher brightness and light extraction efficiency since its surface roughness can be an Rms of 15 nm or more, as compared to the conventional LED that the Zn-doped p-type GaP current spreading layer has a surface roughness Rms of 10 nm or less.

(ii) Since the additional post-process of roughening the surface of the p-type GaP current spreading layer is not needed, the fabrication cost can be reduced.

(iii) Even when the p-type GaP current spreading layer is epitaxially grown thick, the surface defect is less likely to occur. Therefore, the yield of the chip process can be enhanced.

(iv) Since the p-type GaP current spreading layer can be formed thick, the current can be more spread laterally and the light extraction efficiency can be further enhanced.

### Second Embodiment

An epitaxial wafer of the second preferred embodiment of the invention is characterized by that the p-type GaP current spreading layer 6 has a predetermined surface roughness by co-doping Mg and C. The other composition thereof is the same as the first embodiment.

The Mg, C-doped p-type current spreading layer 6 is epitaxially grown at a V/III ratio of 1 to 100 by using trimethylgallium (=Ga (CH₃)₃) and/or triethylgallium (=Ga(C₂H₅)₃), while co-doping Mg and C respectively at an atom concentration of 1×10¹⁷ cm⁻³ or more. Thus, the p-type GaP current spreading layer 6 has a root mean square roughness Rms of 20 nm or more.

In the second embodiment, the p-type GaP current spreading layer 6 has a surface roughness more than the embodiment. Therefore, the epitaxial wafer for LED and the light emitting diode can have a higher brightness and light extraction efficiency.

### EXAMPLE 1

An epitaxial wafer or LED of Example 1 corresponds to the first embodiment as described above.

The epitaxial wafer or LED of Example 1 is fabricated as described below.

First, the 0.5 μm thick n-type AlGaInP cladding layer 3 with a carrier concentration of 1×10¹⁸ cm⁻³, the 0.5 μm thick undoped AlGaInP active layer 4, and the 0.5 μm thick p-type AlGaInP cladding layer 5 with a carrier concentration of 5×10¹⁷ cm⁻³ are sequentially grown on the n-type GaAs substrate 2 by MOVPE.

Then, the 10 μm thick Mg-doped p-type GaP current spreading layer 6 with a carrier concentration of 1×10¹⁸ cm⁻³ is grown on the p-type AlGaInP cladding layer 5 by MOVPE.

The p-type GaP current spreading layer 6 is grown by flowing phosphine (PH₃) at 1000 cc/min, trimethylgallium (TMG: (CH₃)₃Ga) at 50 cc/min, biscyclopentadienyl magnesium (Cp₂Mg) at 200 cc/min, and H₂ carrier gas at 20 L/min, at a growth temperature of 700° C. for about 2 hours.

(Evaluation)

When the surface roughness of the p-type GaP current spreading layer 6 is evaluated using an atomic force microscope, it is determined Rms 20 nm.

Further, an LED chip of 350 μm square is made from the epitaxial wafer fabricated as described above. The LED chip is evaluated in emission characteristic. The emission output is increased to 2.1 mW which is about 15% higher than an LED chip with the Zn-doped GaP current spreading layer (with a surface roughness Rms of 7 nm) formed thereon.

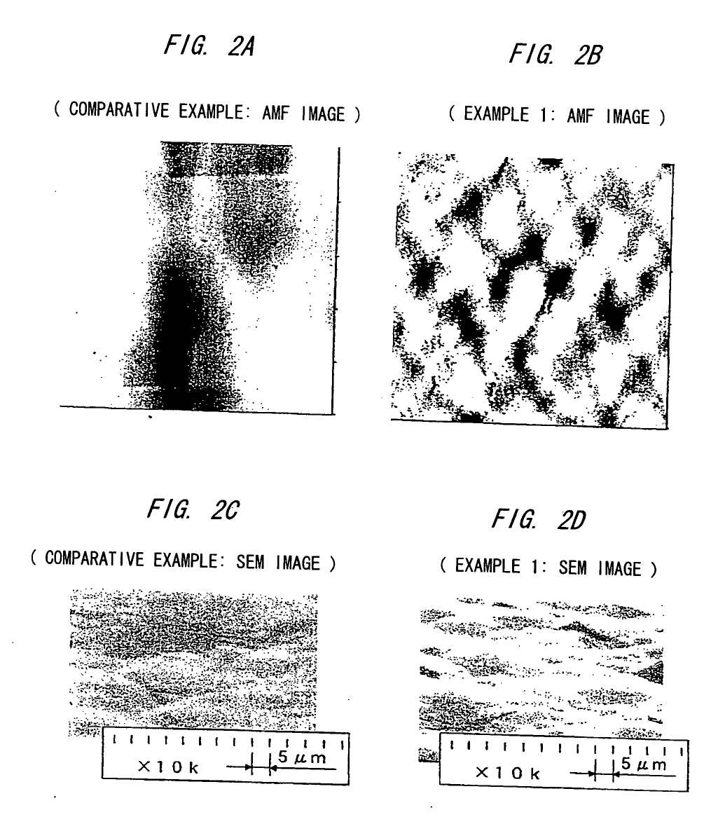

FIGS. 2A to 2D are photographs showing a difference in surface roughness between Example 1 and an LED with the Zn-doped GaP layer. FIG. 2A (Comparative example) is the photograph (AFM image) showing a surface roughness Rms=7 nm of the Zn-doped GaP layer (with a thickness of 10 μm), FIG. 2B (Example 1) is the photograph (AFM image) showing a surface roughness Rms=20 nm of the Mg-doped GaP layer (with a thickness of 10 μm), FIG. 2C (Comparative example) is the photograph (SEM image) showing a surface roughness Rms=7 nm of the Zn-doped GaP layer (with a thickness of 10 μm), and FIG. 2D (Example 1) is the photograph (SEM image) showing a surface roughness Rms=20 nm of the Mg-doped GaP layer (with a thickness of 10 μm).

In view of the photographs, it is understood that the p-type GaP current spreading layer 6 of Example 1 can have a surface roughness more than the Zn-doped GaP layer of Comparative example.

### EXAMPLE 2

An epitaxial wafer or LED of Example 2 corresponds to the second embodiment as described above.

The epitaxial wafer or LED of Example 2 is fabricated as described below.

First, the 0.5 μm thick n-type AlGaInP cladding layer 3 with a carrier concentration of 1×10¹⁸ cm⁻³, the 0.5 μm thick undoped AlGaInP active layer 4, and the 0.5 μm thick p-type AlGaInP cladding layer 5 with a carrier concentration of 5×10¹⁷ cm⁻³ are sequentially grown on the n-type GaAs substrate 2 by MOVPE.

Then, the 10 μm thick Mg, C-doped p-type GaP current spreading layer 6 with a carrier concentration of 1×10¹⁸ cm⁻³ is grown on the p-type AlGaInP cladding layer 5 by MOVPE.

The p-type GaP current spreading layer 6 is grown by flowing phosphine (PH₃) at 200 cc/min, trimethylgallium (TMG: (CH₃)₃Ga) at 50 cc/min, biscyclopentadienyl magnesium (Cp₂Mg) at 100 cc/min, and H₂ carrier gas at 20 L/min, at a growth temperature of 700° C. for about 2 hours.

(Evaluation)

When the surface roughness of the p-type GaP current spreading layer 6 is evaluated using the atomic force microscope, it is determined Rms 20 nm.

Further, an LED chip of 350 μm square is made from the epitaxial wafer fabricated as described above. The LED chip is evaluated in emission characteristic. The emission output is increased to 2.2 mW which is about 15% higher than the LED chip with the Zn-doped GaP current spreading layer (with a surface roughness Rms of 7 nm) formed thereon.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. An epitaxial wafer for a light emitting diode,
comprising:
a light-emitting portion comprising a n-type cladding layer, a p-type cladding layer and an active layer formed between the n-type cladding layer and the p-type cladding layer, the light-emitting portion being formed on a n-type substrate; and
a p-type GaP current spreading layer formed on the light-emitting portion,
wherein the p-type GaP current spreading layer is doped with Mg and comprises a root mean square roughness Rms of 15 nm to 5 μm on its surface.

2. The epitaxial wafer according to claim 1, wherein:
the p-type GaP current spreading layer is doped with C in addition to the Mg.

3. The epitaxial wafer according to claim 1, wherein:
the p-type GaP current spreading layer is grown by MOVPE by using a biscyclopentadienyl magnesium as a source of the Mg.

4. The epitaxial wafer according to claim 2, wherein:
the p-type GaP current spreading layer is autodoped with C that is contained in an organic metal material comprising Ga.

5. The epitaxial wafer according to claim 1, wherein:
the p-type GaP current spreading layer comprises the Mg at an atomic concentration of 1×10¹⁷ cm⁻³ or more.

6. The epitaxial wafer according to claim 2, wherein:
the p-type GaP current spreading layer comprises the Mg and the C respectively at an atomic concentration of 1×10¹⁷ cm⁻³ or more.

7. The epitaxial wafer according to claim 1, wherein:
the n-type substrate comprises GaAs, and the light-emitting portion comprises AlGaInP or GaInP.

8. A light emitting diode, comprising:
an epitaxial wafer that comprises a light-emitting portion comprising a n-type cladding layer, a p-type cladding layer and an active layer formed between the n-type cladding layer and the p-type cladding layer, the light-emitting portion being formed on a surface of a n-type substrate, and a p-type GaP current spreading layer formed on the light-emitting portion, wherein the p-type GaP current spreading layer is doped with Mg and comprises a root mean square roughness Rms of 15 nm to 5 μm on its surface;
a back surface electrode formed on a surface of the n-type substrate that is opposite to the surface on which the light-emitting portion is formed; and
a surface electrode formed on the p-type GaP current spreading layer.

9. The light emitting diode according to claim 8, wherein:
the p-type GaP current spreading layer is doped with C in addition to the Mg.

10. The light emitting diode according to claim 8, wherein:
the p-type GaP current spreading layer is grown by MOVPE by using a biscyclopentadienyl magnesium as a source of the Mg.

11. The light emitting diode according to claim 9, wherein:
the p-type GaP current spreading layer is autodoped with C that is contained in an organic metal material comprising Ga.

12. The light emitting diode according to claim 8, wherein:
the p-type GaP current spreading layer comprises the Mg at an atomic concentration of 1×10¹⁷ cm⁻³ or more.

13. The light emitting diode according to claim 9, wherein:
the p-type GaP current spreading layer comprises the Mg and the C respectively at an atomic concentration of 1×10¹⁷ cm⁻³ or more.

14. The light emitting diode according to claim 8, wherein:
the n-type substrate comprises GaAs, and
the light-emitting portion comprises AlGaInP or GaInP.
